(19) United States
(12) Patent Application Publication
(10) Pub. No.: US 2025/0199129 A1
(43) Pub. Date: Jun. 19, 2025

(54) LIGHT-RECEIVING ELEMENT AND ELECTRONIC APPARATUS

(71) Applicant: SONY SEMICONDUCTOR SOLUTIONS CORPORATION, KANAGAWA (JP)

(72) Inventors: TAKUYA SEKIGUCHI, KANAGAWA (JP); KAZUKI NAKAI, KANAGAWA (JP); TAKAYUKI MURAKAMI, KANAGAWA (JP)

(21) Appl. No.: 18/843,619

(22) PCT Filed: Jan. 30, 2023
(86) PCT No.: PCT/JP2023/002873

§ 371 Date: Sep. 3, 2024

(30) Foreign Application Priority Data
Mar. 10, 2022 (JP) 2022-037567

(51) Int. Cl. G01S 7/481; G01S 7/4865; G01S 17/10; H04N 25/705

(52) U.S. Cl. CPC G01S 7/4816; G01S 7/4865; G01S 17/10; H04N 25/705

(57) ABSTRACT

Provided is a light-receiving element and an electronic apparatus capable of suppressing saturation of a counter circuit. The present disclosure provides a light-receiving element including a plurality of pixels, in which each of the plurality of pixels includes a sensing circuit that allows detection of incidence of a photon, and a counter circuit that counts a pulse output from the sensing circuit, and in a first mode, at least one first counter circuit among a plurality of counter circuits included in the plurality of pixels counts on the basis of an output value of a second counter circuit different from the first counter circuit among the plurality of counter circuits.

### TECHNICAL FIELD

The present disclosure relates to a light-receiving element and an electronic apparatus.

### BACKGROUND ART

There is known a light-receiving element provided with, for every pixel, a sensing circuit including a single-photon avalanche diode (SPAD) that detects the presence or absence of a photon and a counter circuit that counts the number of photons. However, in a case where a background light amount is large, there is a possibility that the counter circuit is saturated.

### CITATION LIST

### Patent Document

Patent Document 1: Patent Document 1: Japanese Patent Application Laid-Open No. 2020-10093

### SUMMARY OF THE INVENTION

### Problems to be Solved by the Invention

The present disclosure therefore provides a light-receiving element and an electronic apparatus capable of suppressing saturation of a counter circuit.

### Solutions to Problems

In order to solve the problem described above, the present disclosure provides
a light-receiving element including a plurality of pixels, in which
each of the plurality of pixels includes
a sensing circuit that allows detection of incidence of a photon, and
a counter circuit that counts a pulse output from the sensing circuit, and
in a first mode, at least one first counter circuit among a plurality of counter circuits included in the plurality of pixels counts on the basis of an output value of a second counter circuit different from the first counter circuit among the plurality of counter circuits.

In a second mode, the first counter circuit may count a pulse signal of a first sensing circuit corresponding among a plurality of the sensing circuits included in the plurality of pixels.

In the first mode, the second counter circuit may count a pulse signal of a second sensing circuit different from the first sensing circuit among the plurality of sensing circuits included in the plurality of pixels.

A control processing circuit that performs control processing on the plurality of pixels may be further included.

In a case where controlling in the second mode, the control processing circuit may control a first multi-pixel corresponding to the first counter circuit and the second counter circuit in the first mode in response to a case where a counter value of the first counter circuit or the second counter circuit exceeds a predetermined upper limit value.

In a case where controlling the first multi-pixel in the first mode, the control processing circuit may control the first multi-pixel in the second mode in response to a case where the counter value of the first counter circuit and the second counter circuit does not exceed a predetermined upper limit value.

The control processing circuit may include a histogram creator that counts a counter number output from each of the plurality of counter circuits at a predetermined cycle and creates a histogram in which the counter number is arranged in time series.

In the first mode, the histogram creator may create a first histogram obtained by adding an output value of the first counter circuit and an output value of the second counter circuit.

In the first mode, the histogram creator may create a histogram based on the output value of the first counter circuit and a second histogram based on the output value of the second counter circuit.

The control processing circuit may further include a display controller that causes a display unit to display the first histogram or the second histogram.

The first counter circuit may include
a first selection element to which a signal is input from each of the first sensing circuit and the second counter circuit, and
a first bit counter that counts on the basis of an output signal of the first selection element, and
the control processing circuit may perform control of causing the first selection element to select an output signal of the second counter circuit in the first mode and to select an output signal of the first sensing circuit in the second mode.

The first counter circuit may include
a first selection element to which a signal is input from each of the first sensing circuit and the second counter circuit, and
a first bit counter that counts on the basis of the output signal of the first selection element, and
the control processing circuit may perform control of
causing the first selection element to select the output signal of the first sensing circuit at a first cycle in the second mode, and
causing the output signal of the first sensing circuit and the second counter circuit to be selected alternately at a second cycle that is twice the first cycle in the first mode.

The second counter circuit may include
a second selection element to which a signal is input from each of the second sensing circuit and the first counter circuit, and
a second bit counter that counts on the basis of an output signal of the second selection element, and
the control processing circuit may perform control of causing an output signal of the first counter circuit and the second sensing circuit to be selected alternately at the second cycle in the first mode.

The first sensing circuit may further include
an avalanche photodiode,
a resistor connected in series to the avalanche photodiode between a power supply terminal and a ground terminal, and
a waveform shaping circuit that shapes an output signal of the avalanche photodiode into the pulse.

The control processing circuit may select a first region having a high average luminance value on the basis of image data acquired from a first imaging unit and selects the second sensing circuit from a region corresponding to an inside of the first region.

The control processing circuit may select the first sensing circuit from a region corresponding to an outside of the first region.

The control processing circuit may select a third region having a large change in luminance value on the basis of image data acquired from a second imaging unit and selects the second sensing circuit from a region corresponding to an inside of the third region.

The control processing circuit may select the first sensing circuit from a region corresponding to an outside of the third region.

Each of the plurality of pixels may be independently drivable and include a first pixel group and a second pixel group corresponding to the sensing circuit, and
in the first mode,
a pulse signal from a first sensing circuit group including the second sensing circuit may be acquired from the first pixel group, and
a pulse signal from a second sensing circuit group that does not correspond to the first sensing circuit group may be acquired from the second pixel group.

A plurality of combinations of the first sensing circuit and the second sensing circuit may be included, and
the control processing circuit may select from the combinations in accordance with a priority in the first mode.

In a case where the counter circuit corresponding to the sensing circuit adjacent to the second sensing circuit exceeds a predetermined upper limit value in the first mode, the control processing circuit may select the sensing circuit exceeding the predetermined upper limit value as the first sensing circuit.

In order to solve the above problem, the present disclosure provides
an electronic apparatus including the light-receiving element described above, and
an optical system that supplies return light to the light-receiving element.

### BRIEF DESCRIPTION OF DRAWINGS

FIG. 1 is a block diagram illustrating a configuration example of an electronic apparatus.

FIG. 2 is a diagram illustrating an example of a multilayer structure of a light-receiving element.

FIG. 3 is a plan view illustrating a configuration example of a light-receiving chip.

FIG. 4 is a plan view illustrating a configuration example of a logic chip.

FIG. 5 is a block diagram schematically illustrating a circuit configuration example of an optical element.

FIG. 6 is a diagram illustrating an example of a histogram created by a histogram creator.

FIG. 7 is a diagram illustrating a more detailed configuration example of the inside of the optical element.

FIG. 8 is a diagram illustrating an example of a combination of distance measurement points.

FIG. 9 is a time chart illustrating an example of control of distance measurement points by a control circuit illustrated in FIG. 7.

FIG. 10 is a flowchart illustrating an example of control of the distance measurement points by the control circuit illustrated in FIG. 7.

FIG. 11 is a diagram illustrating an example of a histogram image displayed on a display unit by a display controller.

FIG. 12 is a diagram illustrating an example of a histogram image of another example.

FIG. 13 is a schematic diagram of an external appearance of an electronic apparatus according to a second embodiment.

FIG. 14 is a block diagram illustrating a configuration of a processing circuit according to a second embodiment.

FIG. 15 is a diagram schematically illustrating a processing example of a first region extractor.

FIG. 16 is a flowchart illustrating a processing example of the first region extractor.

FIG. 17 is a schematic diagram of an external appearance of an electronic apparatus according to a third embodiment.

FIG. 18 is a block diagram illustrating a configuration of a processing circuit according to the third embodiment.

FIG. 19 is a diagram schematically illustrating a processing example of a second region extractor.

FIG. 20 is a flowchart illustrating a processing example of a second region extractor 95b.

FIG. 21 is a schematic diagram of an external appearance of an electronic apparatus according to a fourth embodiment.

FIG. 22 is a diagram illustrating an example of a multilayer structure of a light-receiving element according to the fourth embodiment.

FIG. 23 is a diagram illustrating an example of a control system from a control circuit of a first counter unit and a second counter unit.

FIG. 24 is a diagram illustrating an operation example at a time of DR extension of distance measurement points in the light-receiving element according to the fourth embodiment.

FIG. 25 is a diagram illustrating a sequence of a bank (BANK) signal at the time of DR extension.

FIG. 26 is a diagram illustrating an example of a combination of pairs of distance measurement points.

FIG. 27 is a diagram illustrating another example of a combination in the pairs of the distance points.

FIG. 28 is a diagram schematically illustrating priority of a combination of pairs recorded in advance in a recorder.

FIG. 29 is a diagram illustrating an example of control of coupling by a controller.

FIG. 30 is a diagram schematically illustrating an effect of selecting a saturated measurement point.

FIG. 31 is a block diagram illustrating an example of a schematic configuration of a vehicle control system.

FIG. 32 is an explanatory diagram illustrating an example of installation positions of an outside-vehicle information detector and an imaging unit.

### MODE FOR CARRYING OUT THE INVENTION

Hereinafter, a preferred embodiment of the present disclosure will be described in detail with reference to the accompanying drawings. Note that, in the present specification and drawings, components having substantially the same functional configuration are denoted by the same reference signs to avoid the description from being redundant.

### First Embodiment

### [Configuration Example of Electronic Apparatus]

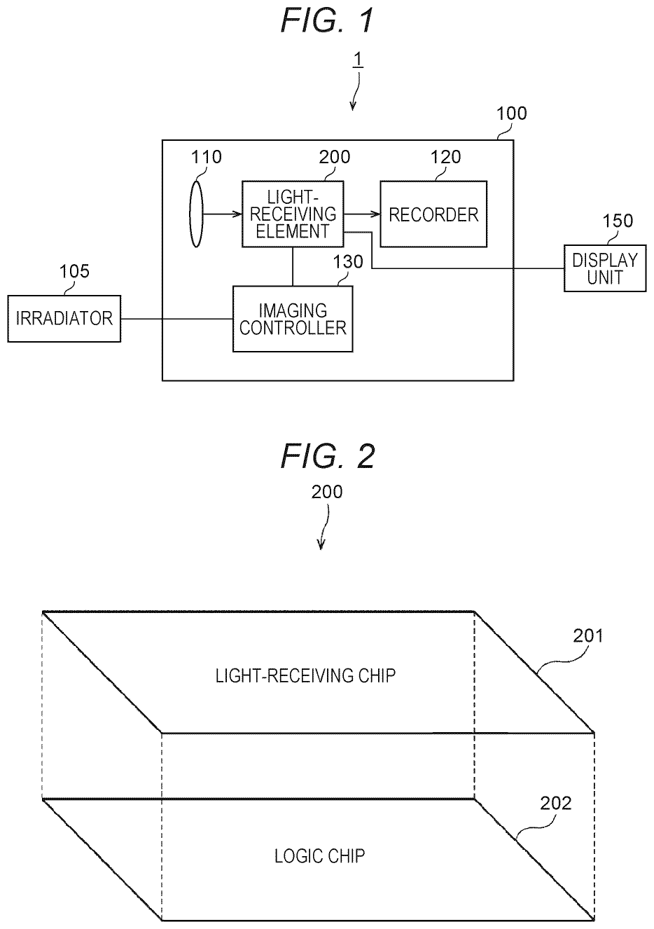

FIG. 1 is a block diagram illustrating a configuration example of an electronic apparatus 1 according to the present embodiment. The electronic apparatus 1 is, for example, an apparatus capable of creating distance image data. That is, the electronic apparatus 1 includes an irradiator 105, an optical system 110, a light-receiving element 200, a recorder 120, an imaging controller 130, and a display unit 150. As the electronic apparatus 1, for example, a smartphone, a digital camera, a personal computer, a vehicle-mounted camera, or an Internet of things (IoT) camera is assumed.

Under the control of the imaging controller 130, the irradiator 105 repeatedly irradiates the light-receiving element with pulsed laser light at preset intervals, and notifies the light-receiving element 200 of the irradiation timing. Note that, in the present embodiment, the cycle of irradiation with laser light is referred to as bank (BANK) time.

The optical system 110 includes, for example, an imaging lens, and condenses return light of a laser and guides the light to the light-receiving element 200. The light-receiving element 200 captures the distance image data under the control of the imaging controller 130. The light-receiving element 200 supplies the captured distance image data to the recorder 120. The recorder 120 records the distance image data and the like.

The imaging controller 130 controls the light-receiving element 200 to capture the distance image data. The imaging controller 130 supplies, for example, a synchronization signal such as a periodic signal FYNC to the irradiator 105 and the light-receiving element 200. Note that the electronic apparatus 1 may further include an interface and transmit image data to outside via the interface, or may display the image data on the display unit 150.

### [Configuration Example of Light-Receiving Element]

FIG. 2 is a diagram illustrating an example of a multilayer structure of the light-receiving element 200 according to an embodiment of the present technology. The light-receiving element 200 includes a light-receiving chip 201 and a logic chip 202 stacked on the light-receiving chip 201. A signal line for transmitting a signal is provided between these chips. The light-receiving element 200 is a so-called photon-counting imaging element.

### [Configuration Example of Light-Receiving Chip]

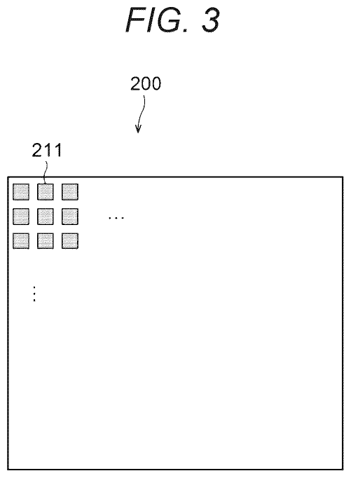

FIG. 3 is a plan view illustrating a configuration example of the light-receiving chip 201 according to an embodiment of the present technology. The light-receiving chip 201 includes a plurality of sensing circuits 211 arranged in a two-dimensional lattice pattern. Furthermore, the sensing circuits 211 each include a single photon avalanche diode (SPAD). In the SPAD, avalanche amplification occurs when one photon enters a PN junction region of a high electric field in a state where a voltage larger than a breakdown voltage is applied. In the sensing circuit 211, that is, in the light-receiving chip 201, a pixel array in which the sensing circuits 211 using the SPADs are arranged in a matrix is adopted. Each of the plurality of sensing circuits 211 outputs a pulse signal in accordance with the sensed photon. In addition, the plurality of sensing circuits 211 constitutes a SPAD sensor 20.

### [Configuration Example of Logic Chip]

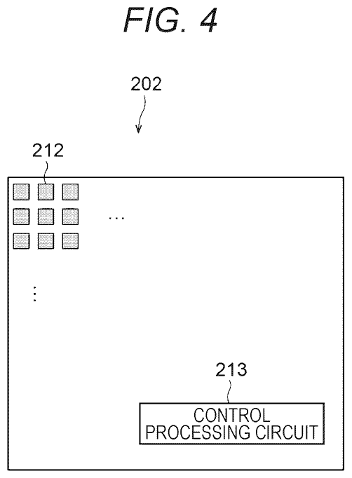

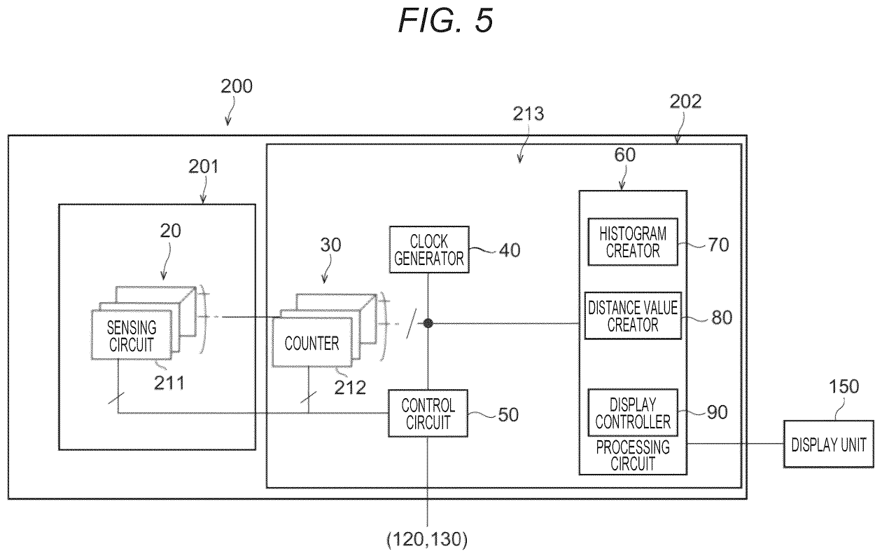

FIG. 4 is a plan view illustrating a configuration example of the logic chip 202 according to the present embodiment. The logic chip 202 is provided with a plurality of counter circuits 212 and a control processing circuit 213. The plurality of counter circuits 212 corresponds to the plurality of sensing circuits 211. Therefore, each of the plurality of counter circuits 212 can count the number of pulse signals output from the corresponding sensing circuit 211.

The counter circuit 212 is, for example, an 8-bit counter. Furthermore, each of the plurality of counter circuits 212 is configured to be able to couple a pair of counter circuits 212. In a case where the pair of counter circuits 212 is coupled, a most significant bit (MSB) of one counter circuit 212 can be input as a least significant bit (LSB) of the other counter circuit 212. Therefore, in a case where the pair of counter circuits 212 is coupled, the number of pulses can be counted up to 16 bits. In this case, for example, the pulse signal of the sensing circuit 211 corresponding to one of the pair of coupled counter circuits 212 is counted. As can be seen, in a case where the counter circuit 212 is coupled, a dynamic range (DR) is doubled. On the other hand, a resolution in the case of coupling is a half of a resolution in the case of not coupling. Note that the plurality of counter circuits 212 constitutes a counter unit 30. Furthermore, a configuration of the sensing circuit 211 according to the present embodiment and the corresponding counter circuit 212 is referred to as a pixel. That is, one pixel includes the sensing circuit 211 and the corresponding counter circuit 212.

The control processing circuit 213 controls the plurality of sensing circuits 211 and the plurality of counter circuits 212. In addition, the control processing circuit 213 creates distance values corresponding to the plurality of sensing circuits 211 on the basis of outputs of the plurality of counter circuits 212, and creates distance image data of two-dimensional coordinates corresponding to the positions of the plurality of sensing circuits 211.

### [Circuit Configuration Example in Optical Element 200]

FIG. 5 is a block diagram schematically illustrating a circuit configuration example of the optical element 200 according to the present embodiment. As described above, the optical element 200 includes the SPAD sensor 20, the counter unit 30, and the control processing circuit 213. Furthermore, the control processing circuit 213 includes, for example, a CPU, and includes a clock generator 40, a control circuit 50, and a processing circuit 60. The processing circuit 60 includes a histogram creator 70, a distance value creator 80, and a display controller 90.

The clock generator 40 generates a clock signal. The control circuit 50 controls the SPAD sensor 20, the counter unit 30, and the processing circuit 60 on the basis of the clock signal. For example, the control circuit 50 outputs counter values of the plurality of counter circuits 212 of the counter unit 30 every predetermined time interval bin in synchronization with a synchronization signal such as a periodic signal FYNC.

In addition, the control circuit 50 determines whether or not each counter circuit 212 is saturated (overflowed). That is, the control circuit 50 can perform control of coupling the pair of counter circuits 212 in a case where any one of the counter circuits 212 is saturated, for example, exceeds 256 (for example, 8 bits) which is a predetermined upper limit value.

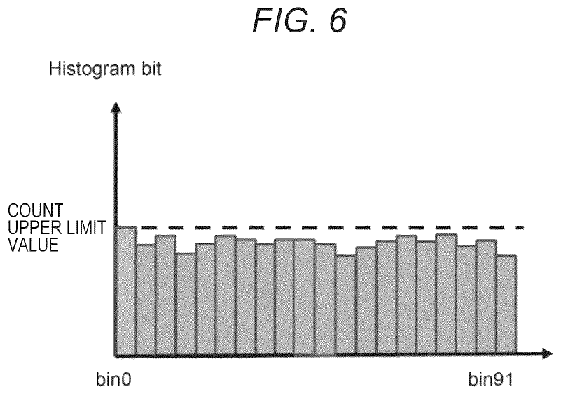

The histogram creator 70 creates a corresponding histogram for every counter circuit 212. FIG. 6 is a diagram illustrating an example of a histogram created by the histogram creator 70. The horizontal axis represents time, and the vertical axis represents the counter value of the counter circuit 212. A count upper limit value corresponds to, for example, 256. The time obtained by adding time intervals bin0 to bin91 corresponds to the bank (BANK) time described above. That is, bin0 starts at a timing when the irradiator 105 emits the pulsed laser light under the control of the imaging controller 130. Then, the next pulsed laser light is emitted when bin91 ends.

As illustrated in FIG. 6, the control circuit 50 causes the histogram creator 70 to output the counter values of the plurality of counter circuits 212 for each of the time intervals bin0 to bin91. Then, the plurality of counter circuits 212 is reset to start counting for the next bin. In this manner, the control circuit 50 repeats outputting and resetting the counter values of the plurality of counter circuits 212 for each of the time intervals bin0 to bin91.

The distance value creator 80 selects bin indicating a maximum value of each histogram created by the histogram creator 70 from the time intervals bin0 to bin91. For example, the timing corresponds to the timing at which the photon reflected from the timing at which the selected bin emits the pulsed laser light returns. As can be seen, the time corresponding to the selected bin is multiplied by the speed of light and divided by two, and then, the obtained value corresponds to the distance value. That is, the distance value creator 80 creates a distance value corresponding to the selected bin for every counter circuit 212. Then, the distance value creator 80 creates distance image data in which each distance value is associated with two-dimensional coordinates. Since each of the plurality of sensing circuits 211 corresponds to two-dimensional coordinates, the distance value creator 80 can create distance image data in which each distance value corresponds to two-dimensional coordinates.

The display controller 90 displays the distance image data on the display unit 150. Furthermore, the display controller 90 can display a histogram image as described later on the display unit 150.

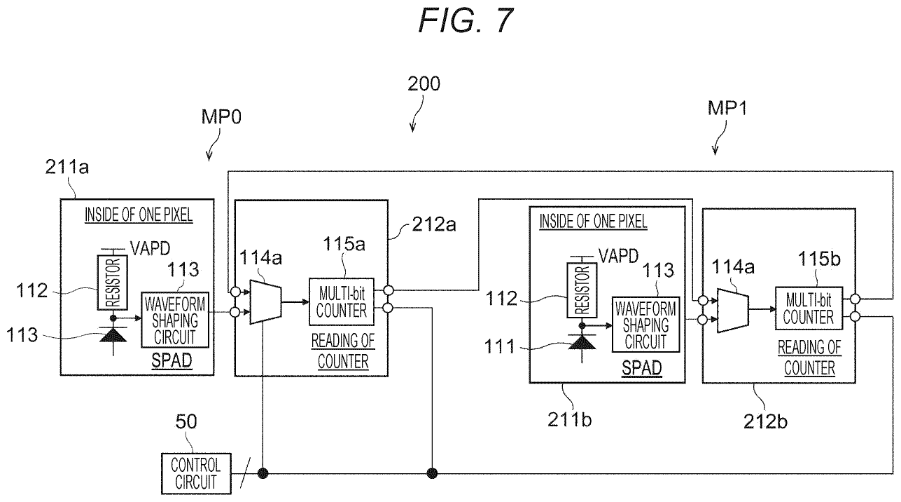

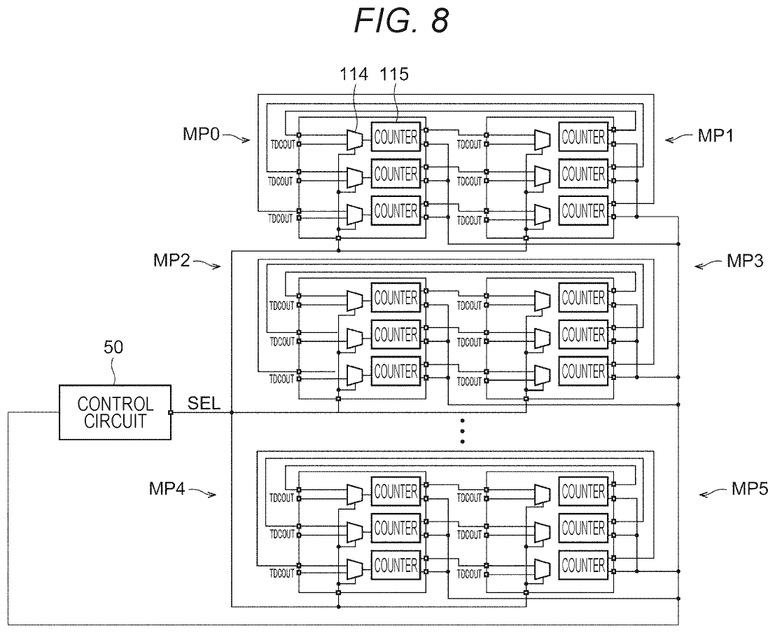

FIG. 7 is a diagram illustrating a more detailed configuration example of the inside of the optical element 200. FIG. 7 illustrates, for the sake of simplicity, a pair of sensing circuit 211a and counter circuit 212a, and a pair of sensing circuit 211b and counter circuit 212b, but the other sensing circuits 211 and counter circuits 212 have a similar configuration. The sensing circuit 211a and the counter circuit 212a represent examples of the sensing circuit 211 and the counter circuit 212 in a distance measurement point MP0 illustrated in FIG. 8 as described later. Similarly, the sensing circuit 211b and the counter circuit 212b represent examples of the sensing circuit 211 and the counter circuit 212 in a distance measurement point MP1 illustrated in FIG. 8 as described later.

As illustrated in FIG. 7, the sensing circuits 211a and 211b include an avalanche photodiode (APD) 111, a quench resistor 112, and a waveform shaping circuit 113. That is, the sensing circuit 211 constitutes a SPAD. The counter circuit 212a includes a multiplexer 114a and a multi-bit counter 115a. Similarly, the counter circuit 212b includes a multiplexer 114b and a multi-bit counter 115b.

A bias voltage VAPD higher than or equal to the breakdown voltage is applied to the APD 111 via the quench resistor 112. When photons enter the APD 111 in this state, then, a large photocurrent flows due to avalanche multiplication, and the voltage drops in the quench resistor 112. Therefore, the bias voltage VAPD applied to the APD 111 decreases, and when the bias voltage VAPD decreases to the breakdown voltage, the avalanche multiplication stops. As a result, the photocurrent stops flowing, and a return to a state where the bias voltage VAPD is applied to the APD 101 is made. The quench resistor 112 is a resistive element for stopping the avalanche multiplication of the APD 111.

The waveform shaping circuit 113 amplifies a voltage at a connection point between the APD 111 and the quench resistor 112 and then performs edge detection to creates voltage pulses as pulse signals from voltage changes caused by incident photons. In this manner, the APD 111, the quench resistor 112, and the waveform shaping circuit 103 constitute the sensing circuit 211 capable of detecting a single incident photon.

In the multiplexer 114a, one terminal of the most significant bit of the paired multi-bit counter 115b is connected to one input terminal, and the waveform shaping circuit 113 of the corresponding sensing circuit 211a is connected to the other input terminal. Furthermore, an output terminal of the multiplexer 114 is connected to the multi-bit counter 115a. Note that the multiplexer 114a according to the present embodiment corresponds to a selection element.

A terminal of the most significant bit of the multi-bit counter 115a is connected to one input terminal of the multiplexer 114b, and a carry bit terminal is connected to the control circuit 50. The multiplexer 114b and the multi-bit counter 115b are similarly connected. That is, a terminal of the most significant bit of the multi-bit counter 115b is connected to one input terminal of the multiplexer 114a, and a carry bit terminal is connected to the control circuit 50.

### (Normal Distance Measurement)

At a time of normal distance measurement, the control circuit 50 sets inputs to the multiplexers 114a and 114b as the corresponding waveform shaping circuit 113. In addition, each of the multi-bit counters 115a and 115b outputs the carry bit to the control circuit 50.

### (DR Extension A)

On the other hand, at the time of dynamic range (DR) extension (at the time of coupled imaging), in a case where the sensing circuit 211a is used, the control circuit 50 sets an input to the multiplexer 114a as the corresponding waveform shaping circuit 113. Furthermore, an input to the multiplexer 114b is set as a terminal of the most significant bit of the multi-bit counter 115a.

### (DR Extension B)

Similarly, at the time of DR extension, in a case where the sensing circuit 211b is used, the control circuit 50 sets an input to the multiplexer 114b as the corresponding waveform shaping circuit 113. Furthermore, an input to the multiplexer 114a is set as a terminal of the most significant bit of the multi-bit counter 115b. Note that the DR extension according to the present embodiment corresponds to a first mode, and the normal distance measurement corresponds to a second mode.

FIG. 8 is a diagram illustrating an example of a combination of distance measurement points MP0 to MP5 according to the present embodiment. As illustrated in FIG. 8, in the present embodiment, a set of three sensing circuits 211 adjacent in a longitudinal direction is set as a distance measurement point MP. In FIG. 8, the distance measurement points MP0 and MP1 are paired, the distance measurement points MP2 and MP3 are paired, and the distance measurement points MP4 and MP5 are paired. For example, the multiplexer 114 and the multi-bit counter 115 in the pair of distance measurement points MP0 and MP1 have a similar connection relationship. Therefore, at the time of DR extension, imaging and non-imaging are controlled by the control circuit 50 for every three sensing circuits 211 adjacent in the longitudinal direction. Note that a light receiving range of laser return light (imaging light) corresponds to each distance measurement point MP.

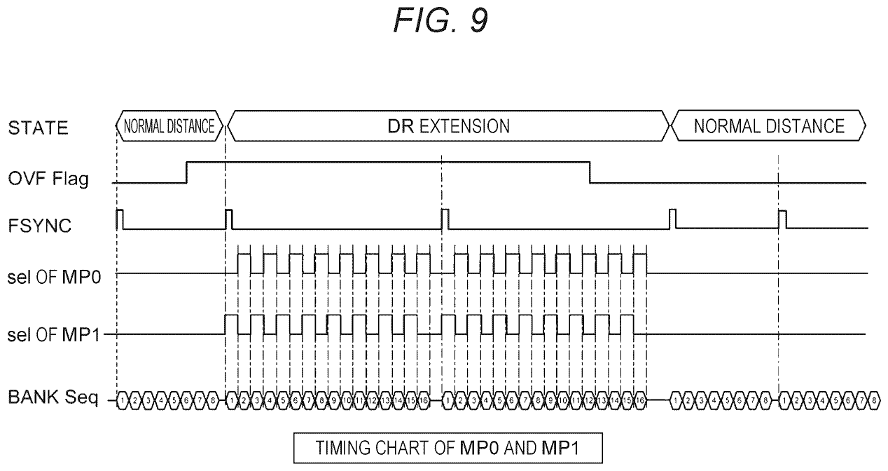

FIG. 9 is a time chart illustrating an example of control of the distance measurement points MP0 and MP1 by the control circuit 50 illustrated in FIG. 7. A state (STAT), an overflow flag (OVF Flg), a periodic signal (FYNC), a selection signal of the distance measurement point MP0 (sel of MP0), a selection signal of the distance measurement point MP1 (sel of MP1), and a sequence (Seq) of bank (BANK) are illustrated from the top. The horizontal axis represents time.

At the time of normal distance measurement in the state (STAT), a drive operation of the (normal distance measurement) described above is performed. On the other hand, at the time of DR extension of the state (STAT), the drive control of the (DR extension A) or (DR extension B) described above is performed.

The overflow flag is a signal based on a detection result of the control circuit 50. A high-level signal indicates that a counter 211 in either the distance measurement point MP0 or MP1 overflows, that is, exceeds a value of 256, for example. On the other hand, a low-level signal indicates that the counter 211 in neither the distance measurement point MP0 nor MP1 overflows. For example, the control circuit 50 can use the carry bit of each counter 211 to sense an overflow.

As described above, the periodic signal FYNC is a synchronization signal output from the imaging controller 130, and is a signal for synchronizing the entire electronic apparatus 1. The imaging controller 130 sets the number of banks to 8 at the time of normal distance measurement, and sets the number of banks to 16 at the time of DR extension. That is, the imaging controller 130 can change the cycle of the periodic signal FYNC in accordance with control information of the control circuit 50.

In a case where the selection signal (sel of the MP0) of the distance measurement point MP0 is a high-level signal, use of the sensing circuit 211a (see FIG. 6) in the MP0 is indicated. That is, the drive control of (DR extension A) described above is performed.

On the other hand, in a case where the selection signal (sel of the MP1) of the distance measurement point MP1 is a high-level signal, use of the sensing circuit 211b (see FIG. 6) in the MP1 is indicated. That is, the drive control of (DR extension B) described above is performed. In this manner, the control circuit 50 controls the overflowed distance measurement point MP0 and the multiplexers 114a and 114b in MP1 in accordance with the sel signal of the MP0 and the sel signal of MP1, and causes an input signal to be selected.

A sequence of sequence (Seq) of bank (BANK) indicates each bank (BANK) time. As described above, one bank corresponds to a cycle in which laser light is emitted. That is, during the normal distance measurement, distance measurement of eight banks is repeated. On the other hand, at the time of DR extension, distance measurement of 16 banks is repeated alternately in (DR extension A) and (DR extension B). Note that, in the present embodiment, in a case where the counters 211 in the distance measurement points MP0 and MP1 overflow, only the distance measurement points MP0 and MP are driven for the DR extension, but the present invention is not limited thereto. For example, a pair of distance measurement points MP2 and MP3 and a pair of distance measurement points MP4 and MP5 may also be driven for the DR extension.

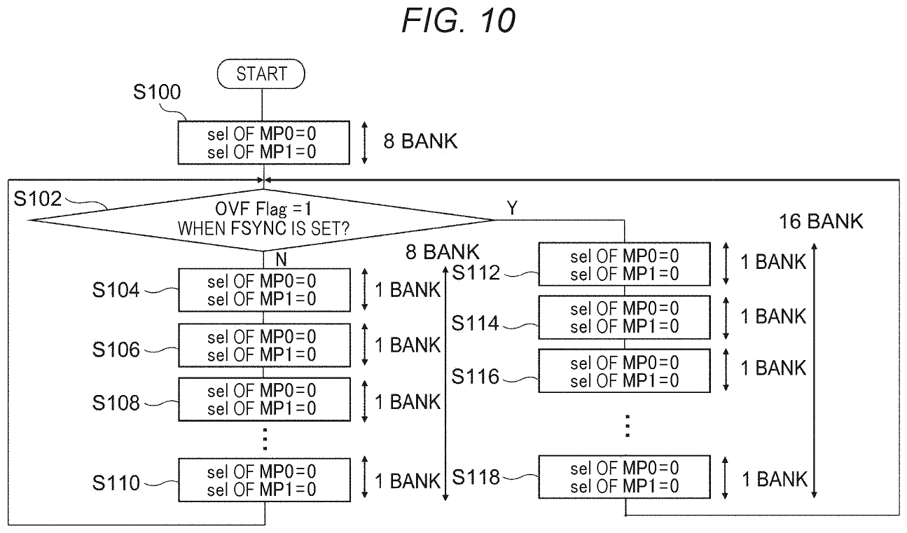

FIG. 10 is a flowchart illustrating an example of control of the distance measurement points MP0 and MP1 by the control circuit 50 illustrated in FIG. 7. As illustrated in FIG. 10, the control circuit 50 starts imaging from a state of the normal distance measurement (step S100). Since the normal distance measurement is performed, the sel of the MP0 and the sel of the MP1 are set to a low level (=0), the multiplexers 114a and 114b are set to each corresponding sensing circuit 211 side, and processing for eight banks is performed.

Next, the control circuit 50 determines whether or not the overflow flag is at a high level (=1) when the periodic signal FYNC is at a high level (step S102). In a case where the overflow flag is at a low level (=0) (N in step S102), the normal distance measurement is performed. Thus, the sel of the MP0 and the sel of the MP1 are set to a low level (=0), the multiplexers 114a and 114b are set to each corresponding sensing circuit 211 side, and processing for eight banks is performed. (Steps S104 and S110)

On the other hand, in a case where the overflow flag is at the high level (=1) (Y in step S102), the control circuit 50 performs the control drive of (DR extension A) for one bank by setting the sel of the MP0 to the low level (=0) and setting the sel of MP1 to the high level (=1) because of the DR extension (step S112). Subsequently, the control circuit 50 sets the sel of the MP0 to the high level (=1) and sets the sel of the MP1 to the low level (=0) to perform the control drive of (DR extension B) for one bank (step S114), and then, alternately repeats the drive of (DR extension A) and (DR extension B) for 14 banks (steps S116 to S118). Then, the processing from step S102 is repeated until the imaging of the electronic apparatus 1 ends.

In this manner, when any one of the counters 211 in the distance measurement points MP0 and MP1 overflows, then, the control circuit 50 performs driving in which the two counters 211 forming a pair are coupled to extend the dynamic range. Therefore, even in a case where the light amount of the background light increases, it is possible to perform distance measurement with higher accuracy. In addition, in a case of overflow, by alternately using the outputs of the pair of sensing circuits 211, it is possible to suppress a decrease in resolution of the distance image data. In other words, imaging can be performed without reducing the number of distance measurement points MP0 and MP1. Furthermore, in a case where none of the counters 211 in the distance measurement points MP0 and MP1 has overflowed, the resolution can be further increased by using the outputs of the pair of the sensing circuits 211.

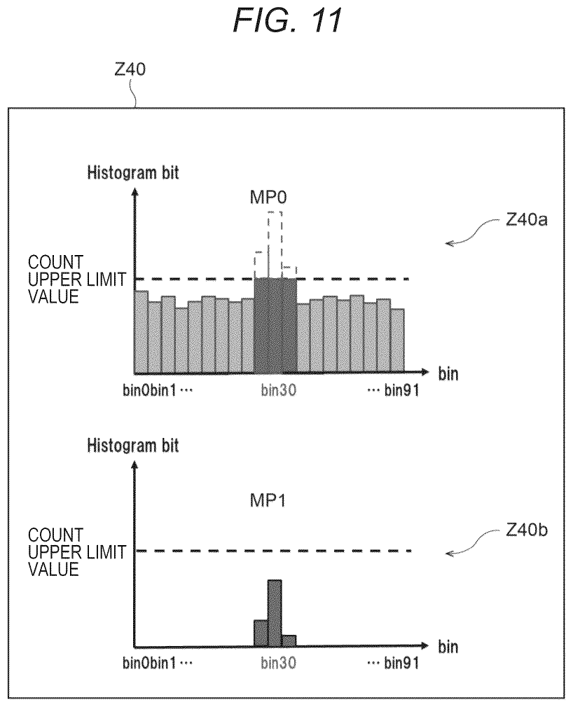

FIG. 11 is a diagram illustrating an example of a histogram image Z40 displayed on the display unit 150 by the display controller 90 in a case where the DR extension A is driven. In the image Z40, a histogram Z240a of the carry bit of the counter 211a and a histogram Z240b of the carry bit of the counter 211b in the histogram distance measurement point MP0 are vertically arranged and displayed. It is therefore easy to know the overflowed bin and the value at that time.

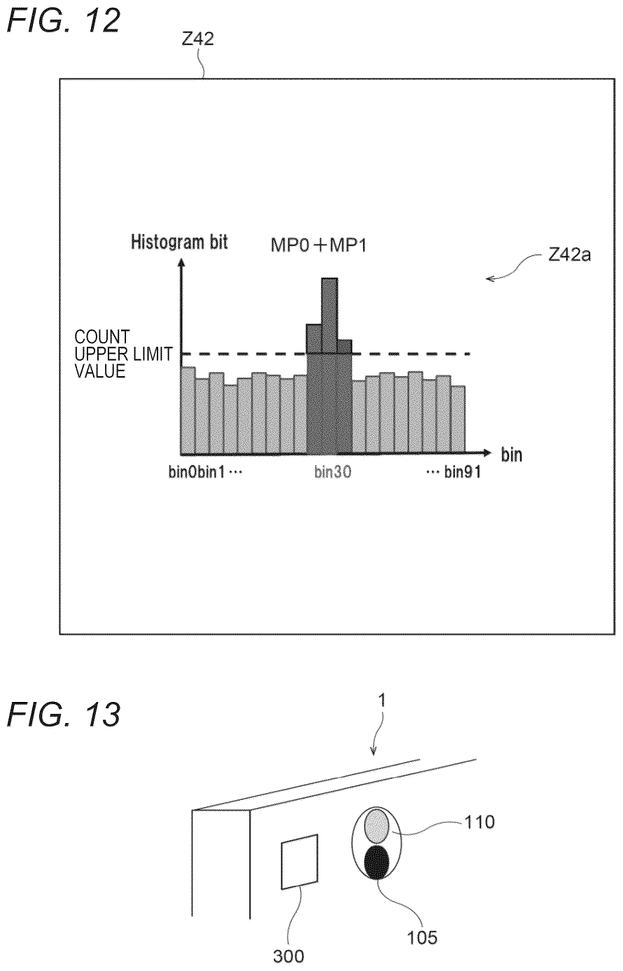

FIG. 12 is a diagram illustrating an example of another histogram image Z42 displayed on the display unit 150 by the display controller 90 in a case where the DR extension A is driven. In the image Z42, a histogram obtained by adding the value of the carry bit of the counter 211a and the value of the carry bit of the counter 211b is displayed. Therefore, the overflowed bin and the entire value can be known from one diagram. The display example of FIG. 10 or 11 can be selected by setting.

As described above, in the present embodiment, when any one of the counters 211 in the distance measurement points MP0 and MP1 overflows, then, the control circuit 50 performs driving in which the two counters 211 forming a pair are coupled. Therefore, a measurement bit depth is doubled, and the dynamic range can be extended. As a result, even in a case where the light amount of the background light increases, it is possible to perform distance measurement with higher accuracy. In addition, in a case of overflow, by alternately using the outputs of the pair of sensing circuits 211, it is possible to suppress a decrease in resolution of the distance image data.

### Second Embodiment

An electronic apparatus 1 according to a second embodiment is different from the electronic apparatus 1 according to the first embodiment in that a range in which DR extension is performed can be set in advance by using information of a visible imaging sensor (RGB sensor). Hereinafter, a difference from the electronic apparatus 1 according to the first embodiment will be described.

FIG. 13 is a schematic diagram of an external appearance of the electronic apparatus 1 according to the second embodiment. As illustrated in FIG. 13, the electronic apparatus 1 according to the second embodiment further includes a visible imaging sensor (RGB sensor) 300. The coordinates of an imaging region of the visible imaging sensor (RGB sensor) and the plurality of sensing circuits 211 have a correspondence relationship, and are recorded in the recorder 120 (see FIG. 1) in advance, for example.

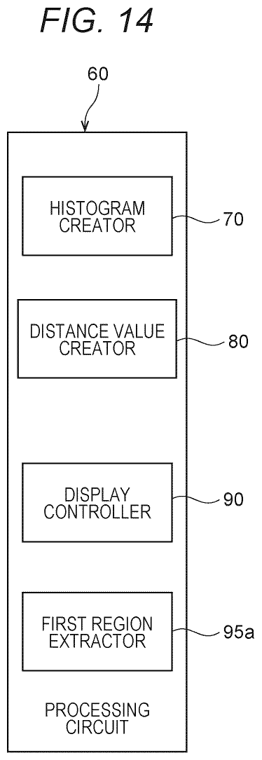

FIG. 14 is a block diagram illustrating a configuration of the processing circuit 60 according to the second embodiment. As illustrated in FIG. 14, the processing circuit 60 according to the second embodiment further includes a first region extractor 95a.

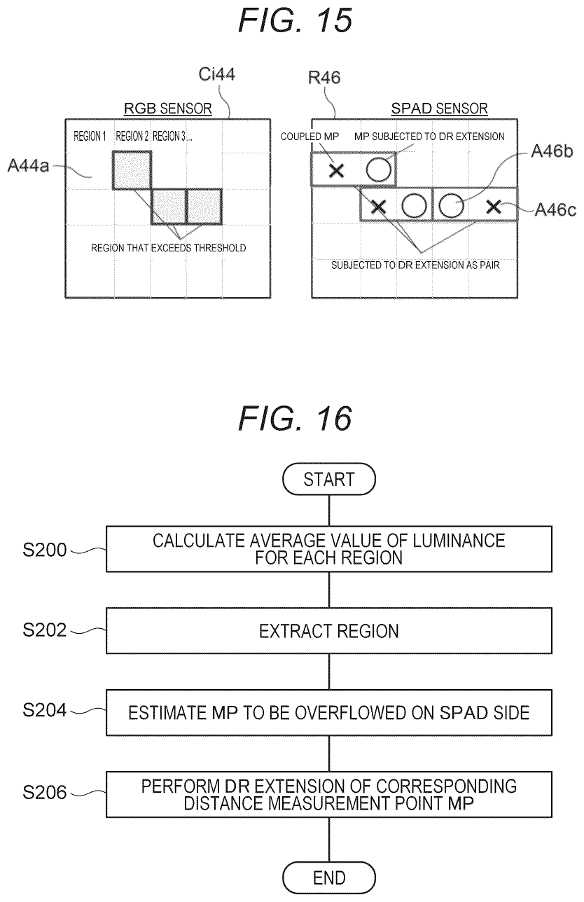

FIG. 15 is a diagram schematically illustrating a processing example of the first region extractor 95a. The first region extractor 95a illustrates a captured image Ci44 of the visible imaging sensor (RGB sensor) 300 and a region R46 of the MP in SPAD sensor 20 (see FIG. 2) including the plurality of sensing circuits 211. FIG. 16 is a flowchart illustrating the processing example of the first region extractor 95a.

With reference to FIG. 15, the processing example of the first region extractor 95a will be described on the basis of FIG. 16. As illustrated in FIG. 16, the first region extractor 95a acquires the captured image Ci44 from the visible imaging sensor (RGB sensor) 300, and calculates an average value of luminance values of regions 1 to N corresponding to the distance measurement points MP1 to MPN (step S200).

Next, the first region extractor 95a extracts a range A44a in which the average value of the luminance values exceeds a threshold Th1 from the regions 1 to N (step S202). Subsequently, the first region extractor 95a estimates the distance measurement point MP that overflows on the SPAD sensor 20 side with the threshold Th1 as a parameter for the average value, and outputs position information of the distance measurement point MP to a controller 50 (step S204).

Then, the controller 50 uses the detection circuit 211 of the distance measurement point MP in a region A46b for detection, and performs DR extension (step S204). Therefore, the counter circuit 212 in a region A46c paired with the counter circuit 212 corresponding to the region A46b is used for DR extension. In this case, since the detection circuit 211 of the distance measurement point MP in the region A46b is always used for distance measurement, for example, the imaging cycle is maintained at eight banks. In this manner, by enabling only the distance measurement point MP (region A46b) at a place where the luminance value of the subject is high, distance measurement can be performed without lowering a frame rate even under strong background light. In addition, it is also possible to automatically switch the distance measurement point MP of the place where the subject is operating in accordance with the next imaging by the visible imaging sensor (RGB sensor) 300.

As described above, in the present embodiment, the captured image Ci44 captured in advance is acquired from the visible imaging sensor (RGB sensor) 300, the detection circuit 211 of the region A46b of the distance measurement point corresponding to the region having the large average value of the luminance values is used for distance measurement, and the counter 211 of the region A46c paired with the counter 211 of the region A46b is used for DR extension. Therefore, since the dynamic range of the region where the average value of the luminance values is large can be extended in advance, it is possible to measure the region A46b in which the possibility that an object exists is high without overflow.

### Third Embodiment

An electronic apparatus 1 according to a third embodiment is different from the electronic apparatus 1 according to the second embodiment in that a range in which DR extension is performed can be further set by using information of an event base vision sensor (EVS). Hereinafter, a difference from the electronic apparatus 1 according to the second embodiment will be described.

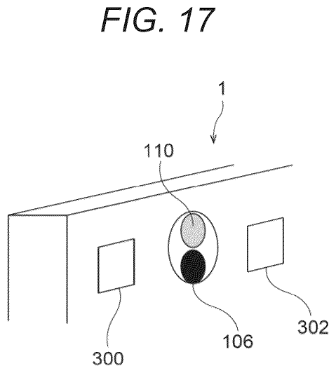

FIG. 17 is a schematic diagram of an external appearance of the electronic apparatus 1 according to the third embodiment. As illustrated in FIG. 17, the electronic apparatus 1 according to the third embodiment further includes an event base vision sensor 302. The coordinates of an imaging region of the event base vision sensor 302 and the plurality of sensing circuits 211 have a correspondence relationship, and are recorded in the recorder 120 (see FIG. 1) in advance, for example.

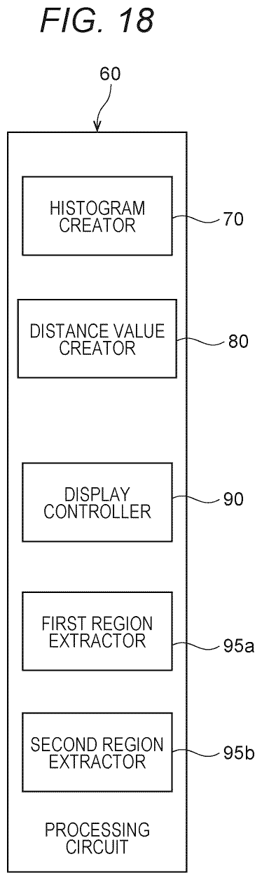

FIG. 18 is a block diagram illustrating a configuration of the processing circuit 60 according to the third embodiment. As illustrated in FIG. 18, the processing circuit 60 according to the third embodiment further includes a second region extractor 95b.

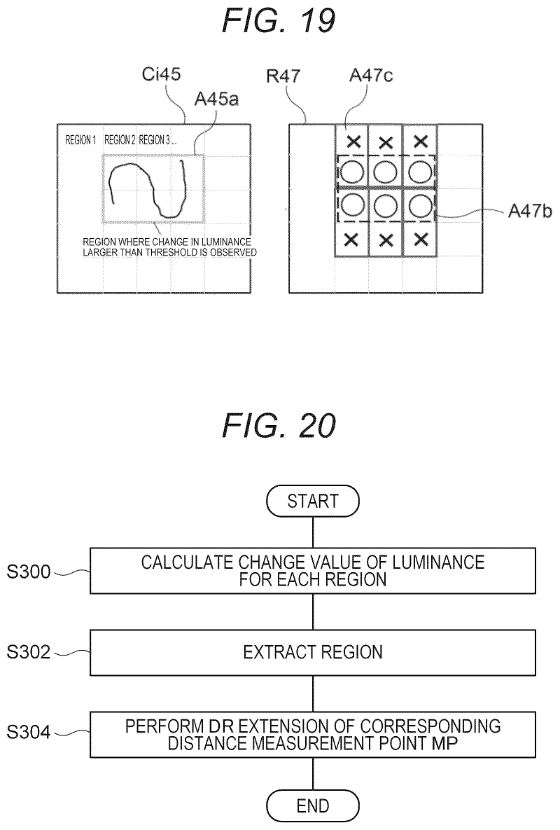

FIG. 19 is a diagram schematically illustrating a processing example of the second region extractor 95b. A captured image Ci45 of the event base vision sensor 302 and the region R46 of the distance measurement point MP in the SPAD sensor 20 (see FIG. 2) are illustrated. FIG. 20 is a flowchart illustrating the processing example of the second region extractor 95b.

With reference to FIG. 19, the processing example of the second region extractor 95b will be described on the basis of FIG. 20. As illustrated in FIG. 20, the second region extractor 95b acquires the captured image Ci45 from the event base vision sensor 300, and calculates a change in luminance values of regions 1 to N corresponding to the distance measurement points MP1 to MPN (step S300).

Next, the second region extractor 95b extracts a range A45a in which the change in the luminance values exceeds a threshold Th2 from the regions 1 to N (step S302). Subsequently, the second region extractor 95b extracts the distance measurement point MP of a region A47b corresponding to the range A45a, and outputs the distance measurement point MP to the controller 50. Then, the controller 50 uses the detection circuit 211 of the distance measurement point MP in a region A47b for detection, and performs DR extension (step S304). Therefore, the counter circuit 212 in a region A47c paired with the counter circuit 212 corresponding to the region A47b is used for DR extension. In this case, since the detection circuit 211 of the distance measurement point MP in the region A46b is always used for distance measurement, for example, the imaging cycle is maintained at eight banks. In this manner, by enabling only the distance measurement point MP (region A47b) at a place where the subject is operating, distance measurement can be performed without lowering a frame rate when there are few regions where the subject is moving under the strong background light. In addition, it is also possible to automatically switch the distance measurement point MP of the place where the subject is operating in accordance with the next imaging by the event base vision sensor 300.

As described above, in the present embodiment, the captured image Ci44 captured in advance is acquired from the event base vision sensor 300, the detection circuit 211 of the region A46b of the distance measurement point corresponding to the region having a large change in the luminance value is used for distance measurement, and the counter 211 of the region A46c paired with the counter 211 of the region A46b is used for DR extension. Therefore, since the dynamic range of the region where the change in the luminance value is large can be extended in advance, it is possible to measure the region A46b in which the possibility that an object exists is high without overflow.

### Fourth Embodiment

An electronic apparatus 1 according to a fourth embodiment is different from the electronic apparatus 1 according to the third embodiment in that a plurality of SPAD sensors and a plurality of counter units are included. Hereinafter, a difference from the electronic apparatus 1 according to the third embodiment will be described.

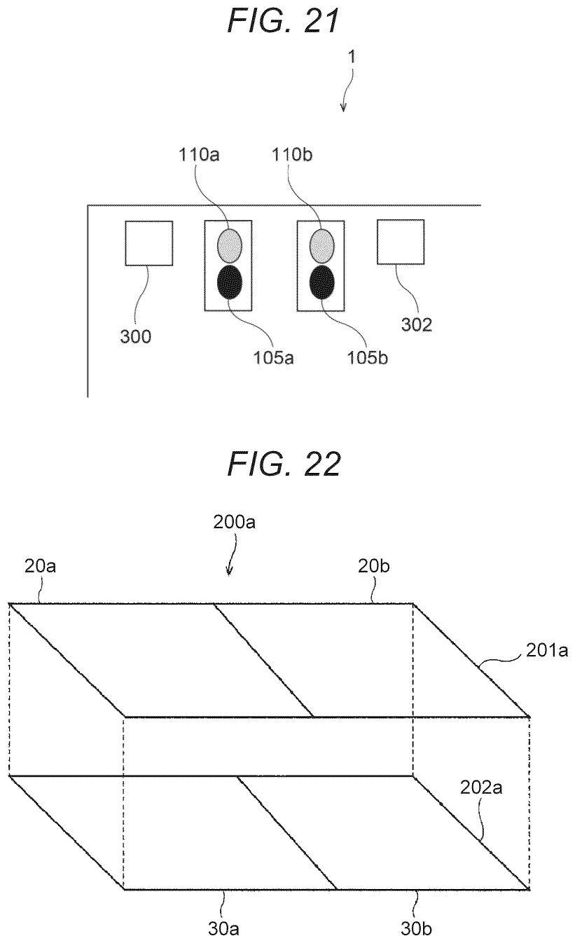

FIG. 21 is a schematic diagram of an external appearance of the electronic apparatus 1 according to the fourth embodiment. As illustrated in FIG. 21, the electronic apparatus 1 according to the fourth embodiment includes a plurality of irradiators 105a and 105b and a plurality of light-receiving optical systems 110a and 110b.

### [Configuration Example of Light-Receiving Element]

FIG. 22 is a diagram illustrating an example of a multilayer structure of a light-receiving element 200a according to the fourth embodiment. The light-receiving element 200a includes a light-receiving chip 201a and a logic chip 202a stacked on the light-receiving chip 201a. In addition, the light-receiving chip 201a includes a first SPAD sensor 20a provided with a plurality of sensing circuits 211 in a two-dimensional lattice pattern and a second SPAD sensor 20b provided with a plurality of sensing circuits 211 in a two-dimensional lattice pattern.

The first SPAD sensor 20a receives reflected light of pulsed light irradiated by the irradiator 105a via the light-receiving optical system 110a. Similarly, the second SPAD sensor 20b receives reflected light of pulsed light irradiated by the irradiator 105b via the light-receiving optical system 110b.

In addition, the plurality of sensing circuits 211 of the first SPAD sensor 20a and the second SPAD sensor 20b have a correspondence relationship. That is, the first SPAD sensor 20a and the second SPAD sensor 20b employ a pixel array in which the sensing circuits 211 using SPAD are arranged in a matrix. Furthermore, the first SPAD sensor 20a and the second SPAD sensor 20b can be driven independently or in synchronization.

The logic chip 202a is provided with a first counter unit 30a, a second counter unit 30b, and the control processing circuit 213 (see FIG. 5). The first counter unit 30a includes a plurality of counter circuits 212 corresponding to the sensing circuits 211 of the first SPAD sensor 20a. Similarly, the first counter unit 30b includes a plurality of counter circuits 212 corresponding to the sensing circuits 211 of the second SPAD sensor 20b.

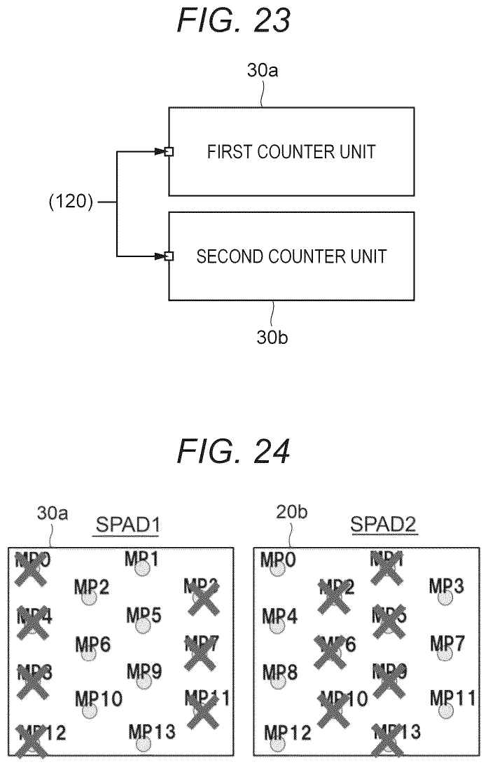

FIG. 23 is a diagram illustrating an example of a control system from the control circuit 50 of the first counter unit 30a and the second counter unit 30b. As illustrated in FIG. 23, the first counter unit 30a and the second counter unit 30b can be driven independently or synchronously under the control of the control circuit 50.

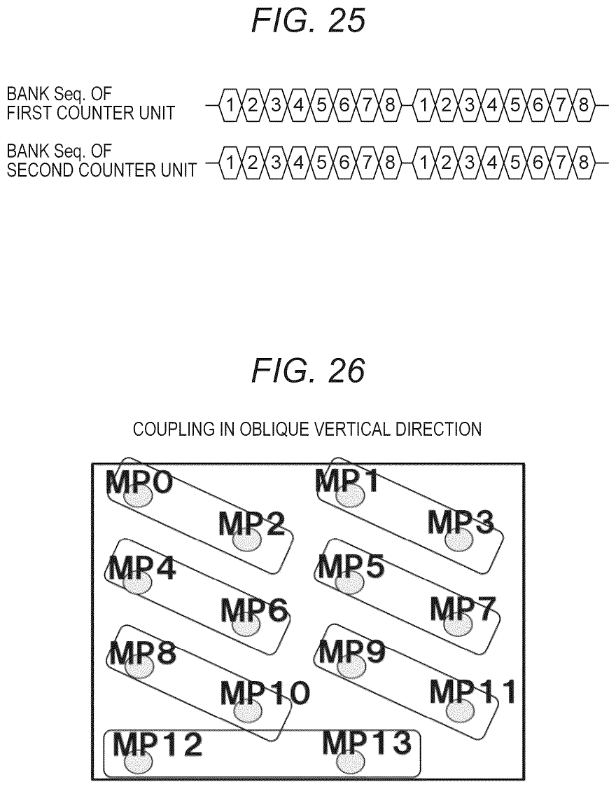

Here, synchronous drive of the first SPAD sensor 20a and the second SPAD sensor 20b at the time of DR extension will be described with reference to FIGS. 24 and 25.

FIG. 24 is a diagram illustrating an operation example at the time of DR extension of the distance measurement points MP in the light-receiving element 200a according to the fourth embodiment. Distance measurement points of the sensing circuit 211 used in the first SPAD sensor 20a are MP1, 2, 5, 6, 9, 10, and 13, and distance measurement points of the sensing circuit 211 used in the second SPAD sensor 20b are MP0, 1, 3, 4, 7, 8, 11, and 12. In addition, the distance measurement points of the counter circuit 212 cooperated on the first SPAD sensor 20a side are the counter circuits 212 corresponding to MP0, 1, 3, 4, 7, 8, 11, and 12, and the distance measurement points of the counter circuit 212 cooperated on the second SPAD sensor 20b side are MP1, 2, 5, 6, 9, 10, and 13. In this manner, the first SPAD sensor 20a and the second SPAD sensor 20b complementarily use the distance measurement points MP to be used. Therefore, a decrease in resolution is also suppressed at the time of DR extension.

FIG. 25 is a diagram illustrating a sequence of a bank (BANK) signal at the time of DR extension. The upper side is a sequence of bank (BANK) signals at the time of DR extension in the first counter unit 30a, and the lower side is a sequence of bank (BANK) signals at the time of DR extension in the second counter unit 30b. In this manner, at the time of DR extension, the control circuit 50 synchronizes the first SPAD sensor 20a and the first counter unit with the second SPAD sensor 20b and the second counter unit 30b. In addition, since the resolution is also maintained, imaging is periodically performed with the number of banks of eight.

As described above, in the present embodiment, the light-receiving element 200a includes the plurality of first SPAD sensors 20a and the first counter unit, and the second SPAD sensor 20b and the second counter unit 30b, and the first SPAD sensor 20a and the second SPAD sensor 20b complementarily use the distance measurement points MP used at the time of DR extension. Therefore, the dynamic range can be extended while maintaining the resolution.

### Fifth Embodiment

An electronic apparatus 1 according to a fifth embodiment is different from the electronic apparatus according to the fourth embodiment in that priorities are given to how to combine pairs of distance measurement points MP0 to MPn.

Hereinafter, a difference from the electronic apparatus 1 according to the fourth embodiment will be described.

FIG. 26 is a diagram illustrating an example of a combination of distance measurement points MP0 to MPn. In FIG. 26, n is 13. FIG. 26 illustrates an example in which the pair is vertically combined.

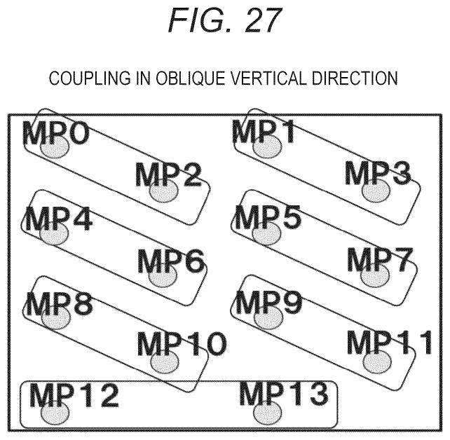

FIG. 27 is a diagram illustrating another example of a combination of pairs of distance measurement points MP0 to MPn. In FIG. 27, n is 13. In FIG. 27, the pair is obliquely combined. In this manner, the electronic apparatus 1 according to the second embodiment has a plurality of methods for combining pairs except in a horizontal direction.

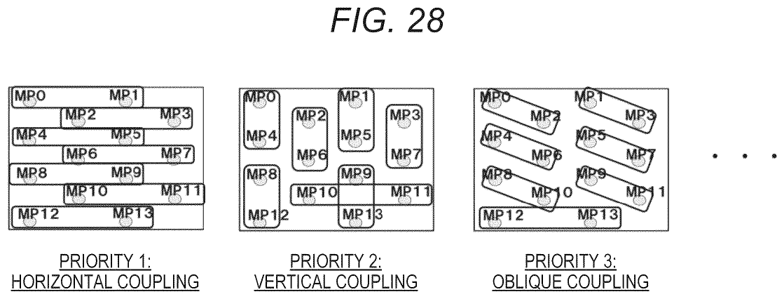

FIG. 28 is a diagram schematically illustrating priorities of a combination of pairs recorded in advance in the recorder 120 (see FIG. 1). As illustrated in FIG. 28, horizontal coupling has a priority 1, vertical coupling has a priority 2, and oblique coupling has a priority 3. These priorities are examples of a case where an adjacent distance measurement point is not saturated.

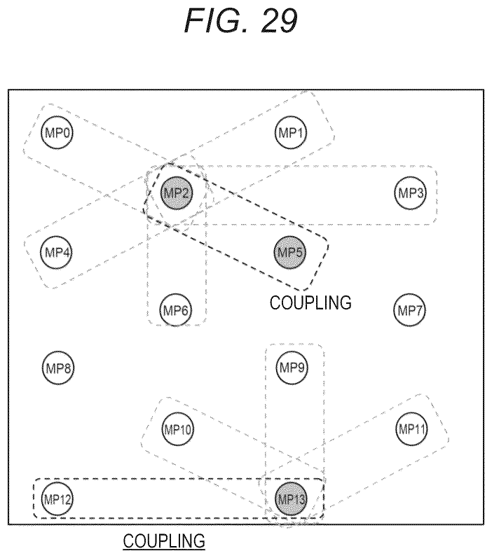

FIG. 29 is a diagram illustrating an example of control of coupling by the controller 50. One example is a case where saturation of the distance measurement point MP2 is sensed. In this case, in a case where the adjacent distance measurement point is not saturated, the distance measurement points are coupled with the priority illustrated in FIG. 29. However, since the adjacent distance measurement point M5 is also saturated, in this case, the distance measurement point is coupled to the counter circuit 212 of the distance measurement point M5. Therefore, since the distance measurement point M5 is also saturated, a decrease in the amount of imaging information is suppressed even when the counter of the distance measurement point M5 is used.

On the other hand, with the distance measurement point MP13 where saturation is sensed, saturation of an adjacent distance measurement point is not sensed. In this case, the distance measurement points are coupled in accordance with the priority. That is, the horizontal coupling has a priority 1, and the horizontal coupling is selected.

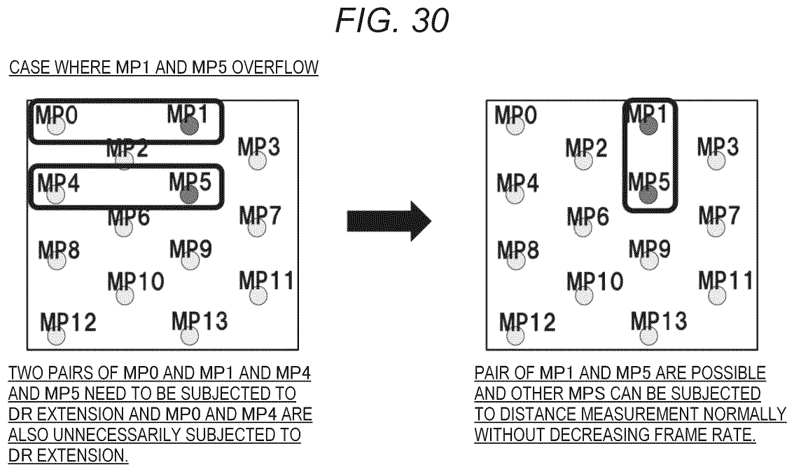

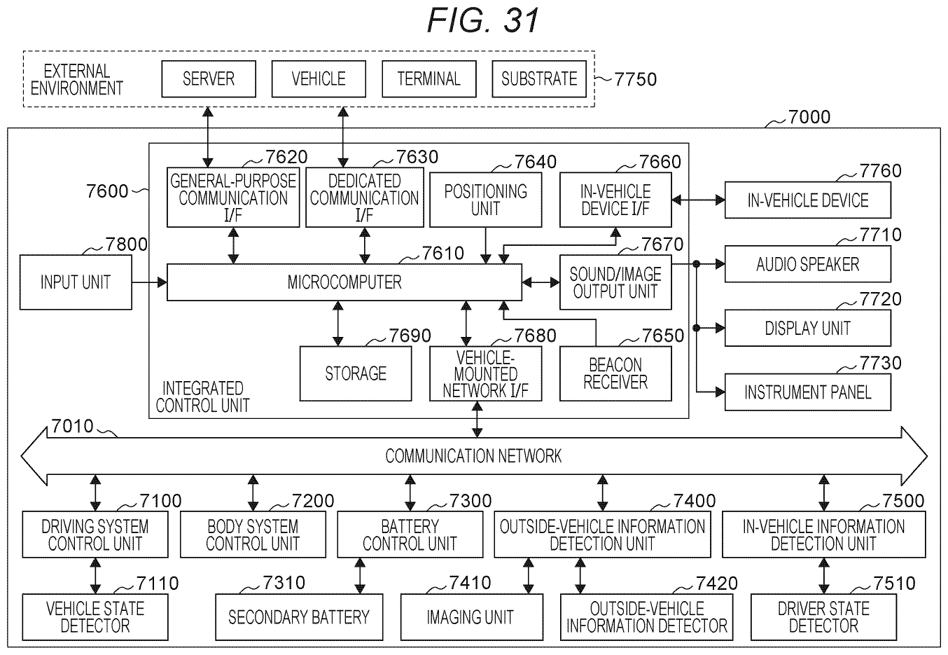

FIG. 30 is a diagram schematically illustrating an effect of selecting a saturated measurement point in a case where the adjacent distance measurement point is saturated. In FIG. 30, the measurement points MP1 and MP5 are saturated. In this case, when MP0 and MP4 are coupled in accordance with the priority 1, the sensing circuits 211 of MP0 and MP4 that are not saturated cannot be used, and the resolution decreases. On the other hand, when the measurement points MP1 and MP5 are coupled while the priority is second, the counter 211 corresponding to the sensing circuit 211 of MP5 that cannot be originally used can be used, and the decrease in resolution can be suppressed.

As described above, in the present embodiment, in a case where there is a saturated measurement point MP and the adjacent measurement point MP is not saturated, the counters 211 are coupled in accordance with the priority. Therefore, even in a case where there is a plurality of saturated measurement points MP, the counters 211 can be regularly coupled, and occurrence of an irregular decrease in resolution can be suppressed. In addition, in a case where there is a saturated measurement point MP, and in a case where the adjacent measurement point MP is saturated, the counter circuits 212 of the saturated fixed points MP are coupled. Therefore, the counter 211 corresponding to the sensing circuit 211 of the measurement point MP that cannot be originally used can be used, and the decrease in resolution can be suppressed.

### Application Example

The technology of the present disclosure can be applied to various products. For example, the technology of the present disclosure may also be implemented as a device mounted on any kind of mobile body such as an automobile, an electric automobile, a hybrid electric automobile, a motorcycle, a bicycle, a personal mobility, an airplane, a drone, a ship, a robot, a construction machine, an agricultural machine (tractor), or the like.

FIG. 31 is a block diagram depicting an example of schematic configuration of a vehicle control system 7000 as an example of a mobile body control system to which the technology according to an embodiment of the present disclosure can be applied. The vehicle control system 7000 includes a plurality of electronic control units connected to each other via a communication network 7010. In the example illustrated in FIG. 31, the vehicle control system 7000 includes a driving system control unit 7100, a body system control unit 7200, a battery control unit 7300, an outside-vehicle information detection unit 7400, an in-vehicle information detection unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes a microcomputer that performs arithmetic processing according to various kinds of programs, a storage that stores the programs executed by the microcomputer, parameters used for various kinds of operations, or the like, and a driving circuit that drives various kinds of control target devices. Each of the control units further includes a network interface (I/F) for performing communication with other control units via the communication network 7010, and a communication I/F for performing communication with a device, a sensor, or the like within and without the vehicle by wire communication or wireless communication. As a functional configuration of the integrated control unit 7600, FIG. 31 illustrates a microcomputer 7610, a general-purpose communication I/F 7620, a dedicated communication I/F 7630, a positioning unit 7640, a beacon receiver 7650, an in-vehicle device I/F 7660, a sound/image output unit 7670, a vehicle-mounted network I/F 7680, and a storage 7690. The other control units similarly include a microcomputer, a communication I/F, a storage, and the like.

The driving system control unit 7100 controls the operation of devices related to the driving system of a vehicle in accordance with various kinds of programs. For example, the driving system control unit 7100 functions as a control device for a driving force generation device for generating the driving force of the vehicle, such as an internal combustion engine, a driving motor, or the like, a driving force transmission mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detector 7110. The vehicle state detector 7110, for example, includes at least one of a gyro sensor that detects the angular velocity of axial rotational movement of a vehicle body, an acceleration sensor that detects the acceleration of the vehicle, or a sensor for detecting an amount of operation of an accelerator pedal, an amount of operation of a brake pedal, the steering angle of a steering wheel, an engine speed or the rotational speed of wheels, or the like. The driving system control unit 7100 performs arithmetic processing using a signal input from the vehicle state detector 7110, and controls the internal combustion engine, the driving motor, an electric power steering device, a brake device, and the like.

The body system control unit 7200 controls the operation of various kinds of devices provided in the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing by using these signals, and performs control for adjusting the temperature of the secondary battery 7310 or controls a cooling device provided in the battery device or the like.

The outside-vehicle information detection unit 7400 detects information about the outside of the vehicle including the vehicle control system 7000. For example, the outside-vehicle information detection unit 7400 is connected with at least one of an imaging unit 7410 or an outside-vehicle information detector 7420. The imaging unit 7410 includes at least one of a time-of-flight (ToF) camera, a stereo camera, a monocular camera, an infrared camera, or another camera. The outside-vehicle information detector 7420, for example, includes at least one of an environmental sensor for detecting current atmospheric conditions or weather conditions and a peripheral information detection sensor for detecting another vehicle, an obstacle, a pedestrian, or the like around the vehicle equipped with the vehicle control system 7000.

The environmental sensor may be, for example, at least one of a rain drop sensor detecting rain, a fog sensor detecting a fog, a sunshine sensor detecting a degree of sunshine, or a snow sensor detecting a snowfall. The peripheral information detection sensor may be at least one of an ultrasonic sensor, a radar device, or a light detection and ranging, or laser imaging detection and ranging (LIDAR) device. Each of the imaging unit 7410 and the outside-vehicle information detector 7420 may be provided as an independent sensor or device, or may be provided as a device in which a plurality of sensors or devices is integrated.

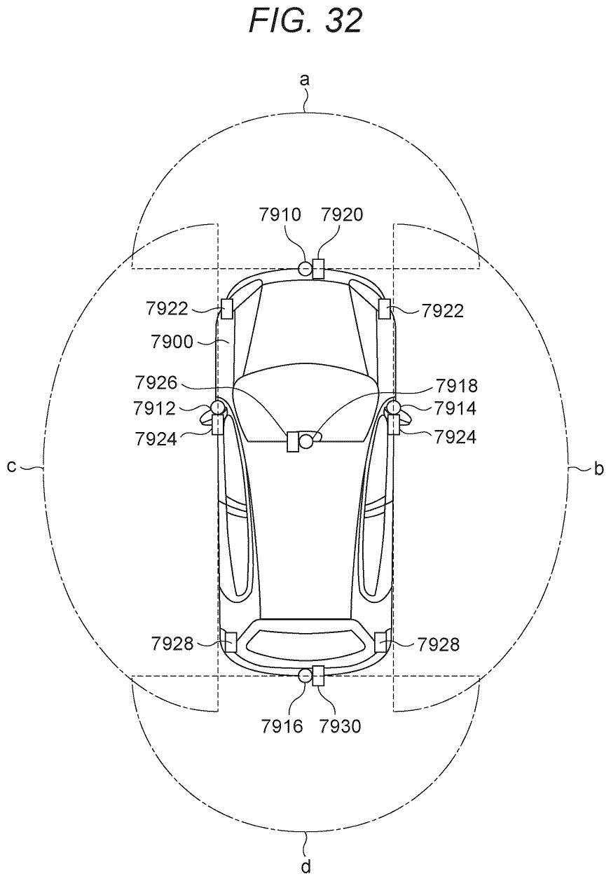

Here, FIG. 32 illustrates an example of installation positions of the imaging unit 7410 and the outside-vehicle information detector 7420. Imaging units 7910, 7912, 7914, 7916, and 7918 are, for example, disposed at at least one of positions on a front nose, sideview mirrors, a rear bumper, or a back door of the vehicle 7900 or a position on an upper portion of a windshield within the interior of the vehicle. The imaging unit 7910 provided on the front nose and the imaging unit 7918 provided at the upper portion of the windshield within the interior of the vehicle acquire mainly an image of the front of the vehicle 7900. The imaging units 7912 and 7914 provided on the sideview mirrors acquire mainly an image of the sides of the vehicle 7900. The imaging unit 7916 provided on the rear bumper or the back door acquires mainly an image of the rear of the vehicle 7900. The imaging unit 7918 provided on the upper portion of the windshield within the interior of the vehicle is used mainly to detect a preceding vehicle, a pedestrian, an obstacle, a signal, a traffic sign, a lane, or the like.

Note that FIG. 32 illustrates an example of an imaging range of each of the imaging units 7910, 7912, 7914, and 7916. An imaging range a indicates the imaging range of the imaging unit 7910 provided on the front nose, imaging ranges b and c indicate the imaging ranges of the imaging units 7912 and 7914 provided on the sideview mirrors, respectively, and an imaging range d indicates the imaging range of the imaging unit 7916 provided on the rear bumper or the back door. A bird's-eye image of the vehicle 7900 as viewed from above can be obtained by superimposing image data captured by the imaging units 7910, 7912, 7914, and 7916, for example.

Outside-vehicle information detectors 7920, 7922, 7924, 7926, 7928, and 7930 provided on the front, rear, sides, and corners of the vehicle 7900 and the upper portion of the windshield within the interior of the vehicle may be, for example, an ultrasonic sensor or a radar device. The outside-vehicle information detectors 7920, 7926, and 7930 provided on the front nose, the rear bumper, and the back door of the vehicle 7900 and on the upper portion of the windshield within the interior of the vehicle may be, for example, a LIDAR device. The outside-vehicle information detectors 7920 to 7930 are used mainly to detect a preceding vehicle, a pedestrian, an obstacle, or the like.

Returning to FIG. 31, the description will be continued. The outside-vehicle information detection unit 7400 causes the imaging unit 7410 to capture an image of the outside of the vehicle, and receives captured image data. In addition, the outside-vehicle information detection unit 7400 receives detection information from the outside-vehicle information detector 7420 connected to the outside-vehicle information detection unit 7400. In a case where the outside-vehicle information detector 7420 is an ultrasonic sensor, a radar device, or a LIDAR device, the outside-vehicle information detection unit 7400 transmits an ultrasonic wave, an electromagnetic wave, or the like, and receives information of a received reflected wave. On the basis of the received information, the outside-vehicle information detection unit 7400 may perform processing of detecting an object such as a human, a vehicle, an obstacle, a sign, a character on a road surface, or the like, or processing of detecting a distance thereto. The outside-vehicle information detection unit 7400 may perform environment recognition processing of recognizing a rainfall, a fog, road surface conditions, or the like on the basis of the received information. The outside-vehicle information detection unit 7400 may calculate a distance to an object outside the vehicle on the basis of the received information.

In addition, on the basis of the received image data, the outside-vehicle information detection unit 7400 may perform image recognition processing of recognizing a human, a vehicle, an obstacle, a sign, a character on a road surface, or the like, or processing of detecting a distance thereto. The outside-vehicle information detection unit 7400 may subject the received image data to processing such as distortion correction, alignment, or the like, and combine the image data imaged by different imaging units 7410 to create a bird's-eye image or a panoramic image. The outside-vehicle information detection unit 7400 may perform viewpoint conversion processing by using the image data imaged by the different imaging units 7410.

The in-vehicle information detection unit 7500 detects information about the inside of the vehicle. The in-vehicle information detection unit 7500 is, for example, connected with a driver state detector 7510 that detects the state of a driver. The driver state detector 7510 may include a camera that images the driver, a biosensor that detects biological information of the driver, a microphone that collects sound within the interior of the vehicle, and the like. The biosensor is, for example, disposed in a seat surface, the steering wheel, or the like, and detects biological information of an occupant sitting in a seat or the driver holding the steering wheel. On the basis of detection information input from the driver state detector 7510, the in-vehicle information detection unit 7500 may calculate a degree of fatigue of the driver or a degree of concentration of the driver, or may determine whether the driver is dozing. The in-vehicle information detection unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input unit 7800. The input unit 7800 is implemented by a device capable of input operation by the occupant, such as, for example, as a touch panel, a button, a microphone, a switch, a lever, or the like. The integrated control unit 7600 may be supplied with data obtained by voice recognition of voice input through the microphone. The input unit 7800 may, for example, be a remote control device using infrared rays or other radio waves, or an external connection device such as a mobile telephone, a personal digital assistant (PDA), or the like that supports operation of the vehicle control system 7000. The input unit 7800 may be, for example, a camera. In that case, the occupant can input information by gesture. Alternatively, data may be input which is obtained by detecting the movement of a wearable device worn by the occupant. Furthermore, for example, the input unit 7800 described above may include an input control circuit or the like that creates an input signal on the basis of information input by the occupant or the like by using the above-described input unit 7800, and which outputs the created input signal to the integrated control unit 7600. The occupant or the like inputs various kinds of data or gives an instruction for processing operation to the vehicle control system 7000 by operating the input unit 7800.

The storage 7690 may include a read only memory (ROM) that stores various kinds of programs executed by the microcomputer and a random access memory (RAM) that stores various kinds of parameters, operation results, sensor values, or the like. In addition, the storage 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system of mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present near the vehicle (which terminal is, for example, a terminal of the driver, a pedestrian, or a store, or a machine type communication (MTC) terminal) by using a peer to peer (P2P) technology, for example.

The dedicated communication I/F 7630 is a communication I/F that supports a communication protocol developed for use in vehicles. The dedicated communication I/F 7630 may implement a standard protocol such as, for example, wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (vehicle to vehicle), communication between a road and a vehicle (vehicle to infrastructure), communication between a vehicle and a home (vehicle to home), and communication between a pedestrian and a vehicle (vehicle to pedestrian).

The positioning unit 7640, for example, performs positioning by receiving a global navigation satellite system (GNSS) signal from a GNSS satellite (for example, a GPS signal from a global positioning system (GPS) satellite), and creates positional information including the latitude, longitude, and altitude of the vehicle. Note that, the positioning unit 7640 may identify a current position by exchanging signals with a wireless access point, or may obtain the positional information from a terminal such as a mobile telephone, a personal handy-phone system (PHS), or a smart phone that has a positioning function.

The beacon receiver 7650, for example, receives a radio wave or an electromagnetic wave transmitted from a radio station installed on a road or the like, and obtains information about the current position, congestion, a closed road, a necessary time, or the like. Note that the function of the beacon receiver 7650 may be included in the dedicated communication I/F 7630 described above.

The in-vehicle device I/F 7660 is a communication interface that mediates connection between the microcomputer 7610 and various in-vehicle devices 7760 that are present in the vehicle. The in-vehicle device I/F 7660 may establish wireless connection by using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not illustrated in the drawings. The in-vehicle devices 7760 may, for example, include at least one of a mobile device or a wearable device possessed by the occupant and an information device carried into or attached to the vehicle. In addition, the in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning unit 7640, the beacon receiver 7650, the in-vehicle device I/F 7660, or the vehicle-mounted network I/F 7680. For example, the microcomputer 7610 may calculate a control target value for the driving force generation device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generation device, the steering mechanism, the braking device, or the like on the basis of the obtained information about the surroundings of the vehicle.

The microcomputer 7610 may create three-dimensional distance information between the vehicle and an object such as a surrounding structure, a person, or the like, and create local map information including information about the surroundings of the current position of the vehicle, on the basis of information obtained via at least one of the general-purpose communication I/F 7620, the dedicated communication I/F 7630, the positioning unit 7640, the beacon receiver 7650, the in-vehicle device I/F 7660, or the vehicle-mounted network I/F 7680. In addition, the microcomputer 7610 may predict danger such as collision of the vehicle, approaching of a pedestrian or the like, an entry to a closed road, or the like on the basis of the obtained information, and create a warning signal. The warning signal may, for example, be a signal for producing a warning sound or lighting a warning lamp.

The sound/image output unit 7670 transmits an output signal of at least one of a sound or an image to an output device capable of visually or auditorily notifying information to an occupant of the vehicle or the outside of the vehicle. In the example of FIG. 12, an audio speaker 7710, a display unit 7720, and an instrument panel 7730 are illustrated as the output device. The display unit 7720 may, for example, include at least one of an on-board display or a head-up display. The display unit 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Note that, in the example illustrated in FIG. 22, at least two control units connected to each other via the communication network 7010 may be integrated into one control unit. Alternatively, each individual control unit may include a plurality of control units. Furthermore, the vehicle control system 7000 may include another control unit not illustrated in the drawings. In addition, in the description above, some or all of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

Note that a computer program for implementing each function of the electronic apparatus 1 according to the present embodiment described with reference to FIG. 1 can be implemented in any of the control units or the like. Furthermore, a computer-readable recording medium in which such a computer program is stored can be provided. The recording medium is, for example, a magnetic disk, an optical disk, a magneto-optical disk, a flash memory, or the like. Furthermore, the computer program described above may be distributed via, for example, a network without using a recording medium.

In the vehicle control system 7000 described above, the electronic apparatus 1 according to the present embodiment described with reference to FIG. 1 can be applied to the imaging unit 7410 of the application example illustrated in FIG. 31.

Furthermore, at least some of the components of the electronic apparatus 1 described with reference to FIG. 1 may be implemented in a module (for example, an integrated circuit module constituted by one die) for the integrated control unit 7600 illustrated in FIG. 31. Alternatively, the electronic apparatus 1 described with reference to FIG. 1 may be implemented by a plurality of control units of the vehicle control system 7000 illustrated in FIG. 31.

Note that the present technology may have the following configurations.

(1)

A light-receiving element includes a plurality of pixels, in which
each of the plurality of pixels includes
a sensing circuit that allows detection of incidence of a photon, and
a counter circuit that counts a pulse output from the sensing circuit, and
in a first mode, at least one first counter circuit among a plurality of counter circuits included in the plurality of pixels counts on the basis of an output value of a second counter circuit different from the first counter circuit among the plurality of counter circuits.

(2)

In the light-receiving element according to (1), in a second mode, the first counter circuit counts a pulse signal of a first sensing circuit corresponding among a plurality of the sensing circuits included in the plurality of pixels.

(3)

In the light-receiving element according to (2), in the first mode, the second counter circuit counts a pulse signal of a second sensing circuit different from the first sensing circuit among the plurality of sensing circuits included in the plurality of pixels.

(4)

The light-receiving element according to (3) further includes a control processing circuit that performs control processing on the plurality of pixels.

(5)

In the light-receiving element according to (4), in a case where controlling in the second mode, the control processing circuit controls a first multi-pixel corresponding to the first counter circuit and the second counter circuit in the first mode in response to a case where a counter value of the first counter circuit or the second counter circuit exceeds a predetermined upper limit value.

(6)

In the light-receiving element according to (5), in a case where controlling the first multi-pixel in the first mode, the control processing circuit controls the first multi-pixel in the second mode in response to a case where the counter value of the first counter circuit and the second counter circuit does not exceed a predetermined upper limit value.

(7)

In the light-receiving element according to (6), the control processing circuit includes a histogram creator that counts a counter number output from each of the plurality of counter circuits at a predetermined cycle and creates a histogram in which the counter number is arranged in time series.

(8)

In the light-receiving element according to (7), in the first mode, the histogram creator creates a first histogram obtained by adding an output value of the first counter circuit and an output value of the second counter circuit.

(9)

The light-receiving element according to (8), in the first mode, the histogram creator creates a histogram based on the output value of the first counter circuit and a second histogram based on the output value of the second counter circuit.

(10)

In the light-receiving element according to (9), the control processing circuit further includes a display controller that causes a display unit to display the first histogram or the second histogram.

(11)

In the light-receiving element according to (4),
the first counter circuit includes
a first selection element to which a signal is input from each of the first sensing circuit and the second counter circuit, and
a first bit counter that counts on the basis of an output signal of the first selection element, and
the control processing circuit performs control of causing the first selection element to select an output signal of the second counter circuit in the first mode and to select an output signal of the first sensing circuit in the second mode.

(12)

In the light-receiving element according to (4),
the first counter circuit includes
a first selection element to which a signal is input from each of the first sensing circuit and the second counter circuit, and
a first bit counter that counts on the basis of the output signal of the first selection element, and
the control processing circuit performs control of
causing the first selection element to select the output signal of the first sensing circuit at a first cycle in the second mode, and
causing the output signal of the first sensing circuit and the second counter circuit to be selected alternately at a second cycle that is twice the first cycle in the first mode.

(13)

In the light-receiving element according to (12),
the second counter circuit includes
a second selection element to which a signal is input from each of the second sensing circuit and the first counter circuit, and
a second bit counter that counts on the basis of an output signal of the second selection element, and
the control processing circuit performs control of causing an output signal of the first counter circuit and the second sensing circuit to be selected alternately at the second cycle in the first mode.

(14)

In the light-receiving element according to (12),
the first sensing circuit includes
an avalanche photodiode,
a resistor connected in series to the avalanche photodiode between a power supply terminal and a ground terminal, and
a waveform shaping circuit that shapes an output signal of the avalanche photodiode into the pulse.

(15)

In the light-receiving element according to (4), the control processing circuit selects a first region having a high average luminance value on the basis of image data acquired from a first imaging unit and selects the second sensing circuit from a region corresponding to an inside of the first region.

(16)

In the light-receiving element according to (15), the control processing circuit selects the first sensing circuit from a region corresponding to an outside of the first region.

(17)

In the light-receiving element according to (4), the control processing circuit selects a third region having a large change in luminance value on the basis of image data acquired from a second imaging unit and selects the second sensing circuit from a region corresponding to an inside of the third region.

(18)

In the light-receiving element according to (17), the control processing circuit selects the first sensing circuit from a region corresponding to an outside of the third region.

(19)

In the light-receiving element according to (4),
each of the plurality of pixels is independently drivable and includes a first pixel group and a second pixel group corresponding to the sensing circuit, and
in the first mode,
a pulse signal from a first sensing circuit group including the second sensing circuit is acquired from the first pixel group, and
a pulse signal from a second sensing circuit group that does not correspond to the first sensing circuit group is acquired from the second pixel group.

(20)

The light-receiving element according to (4) includes a plurality of combinations of the first sensing circuit and the second sensing circuit, in which
the control processing circuit selects from the combinations in accordance with a priority in the first mode.

(21)

In the light-receiving element according to (4), in the first mode,
in a case where the counter circuit corresponding to the sensing circuit adjacent to the second sensing circuit exceeds a predetermined upper limit value, the control processing circuit selects the sensing circuit exceeding the predetermined upper limit value as the first sensing circuit.

(22)

An electronic apparatus includes
the light-receiving element according to (1), and
an optical system that supplies return light to the light-receiving element.

Aspects of the present disclosure are not limited to the above-described individual embodiments, but include various modifications that can be conceived by those skilled in the art, and the effects of the present disclosure are not limited to the above-described contents. That is, various additions, changes, and partial deletions are possible without departing from the conceptual idea and spirit of the present disclosure derived from the matters defined in the claims and equivalents thereof.

### REFERENCE SIGNS LIST

1 Electronic apparatuses
20a First SPAD sensor (first sensing circuit group)
20b Second SPAD sensor (second sensing circuit group)
70 Histogram creator
90 Display controller
110 Optical system
111 Avalanche photodiode
112 Quench resistor
113 Waveform shaping circuit
114 Multiplexer (selection element)
115 Multi-bit counter
200 Optical element
211 Sensing circuit
212 Counter circuit
213 Control processing circuit
300 Visible imaging sensor (RGB sensor)
302 Event base vision sensor (EVS)

1. A light-receiving element comprising a plurality of pixels, wherein
each of the plurality of pixels includes
a sensing circuit that allows detection of incidence of a photon, and
a counter circuit that counts a pulse output from the sensing circuit, and
in a first mode, at least one first counter circuit among a plurality of counter circuits included in the plurality of pixels counts on a basis of an output value of a second counter circuit different from the first counter circuit among the plurality of counter circuits.

2. The light-receiving element according to claim 1, wherein, in a second mode, the first counter circuit counts a pulse signal of a first sensing circuit corresponding among a plurality of the sensing circuits included in the plurality of pixels.

3. The light-receiving element according to claim 2, wherein, in the first mode, the second counter circuit counts a pulse signal of a second sensing circuit different from the first sensing circuit among the plurality of sensing circuits included in the plurality of pixels.

4. The light-receiving element according to claim 3, further comprising a control processing circuit that performs control processing on the plurality of pixels.

5. The light-receiving element according to claim 4, wherein, in a case where controlling in the second mode, the control processing circuit controls a first multi-pixel corresponding to the first counter circuit and the second counter circuit in the first mode in response to a case where a counter value of the first counter circuit or the second counter circuit exceeds a predetermined upper limit value.

6. The light-receiving element according to claim 5, wherein, in a case where controlling the first multi-pixel in the first mode, the control processing circuit controls the first multi-pixel in the second mode in response to a case where the counter value of the first counter circuit and the second counter circuit does not exceed a predetermined upper limit value.

7. The light-receiving element according to claim 6, wherein the control processing circuit includes a histogram creator that counts a counter number output from each of the plurality of counter circuits at a predetermined cycle and creates a histogram in which the counter number is arranged in time series.

8. The light-receiving element according to claim 7, wherein, in the first mode, the histogram creator creates a first histogram obtained by adding an output value of the first counter circuit and an output value of the second counter circuit.

9. The light-receiving element according to claim 8, wherein, in the first mode, the histogram creator creates a histogram based on the output value of the first counter circuit and a second histogram based on the output value of the second counter circuit.

10. The light-receiving element according to claim 9, wherein the control processing circuit further includes a display controller that causes a display unit to display the first histogram or the second histogram.

11. The light-receiving element according to claim 4, wherein
the first counter circuit includes
a first selection element to which a signal is input from each of the first sensing circuit and the second counter circuit, and
a first bit counter that counts on a basis of an output signal of the first selection element, and
the control processing circuit performs control of causing the first selection element to select an output signal of the second counter circuit in the first mode and to select an output signal of the first sensing circuit in the second mode.

12. The light-receiving element according to claim 4, wherein
the first counter circuit includes
a first selection element to which a signal is input from each of the first sensing circuit and the second counter circuit, and
a first bit counter that counts on a basis of the output signal of the first selection element, and
the control processing circuit performs control of
causing the first selection element to select the output signal of the first sensing circuit at a first cycle in the second mode, and
causing the output signal of the first sensing circuit and the second counter circuit to be selected alternately at a second cycle that is twice the first cycle in the first mode.

13. The light-receiving element according to claim 12, wherein
the second counter circuit includes
a second selection element to which a signal is input from each of the second sensing circuit and the first counter circuit,
a second bit counter that counts on a basis of an output signal of the second selection element, and
the control processing circuit performs control of causing an output signal of the first counter circuit and the second sensing circuit to be selected alternately at the second cycle in the first mode.

14. The light-receiving element according to claim 12, wherein
the first sensing circuit includes
an avalanche photodiode,
a resistor connected in series to the avalanche photodiode between a power supply terminal and a ground terminal, and
a waveform shaping circuit that shapes an output signal of the avalanche photodiode into the pulse.

15. The light-receiving element according to claim 4, wherein the control processing circuit selects a first region having a high average luminance value on a basis of image data acquired from a first imaging unit and selects the second sensing circuit from a region corresponding to an inside of the first region.

16. The light-receiving element according to claim 15, wherein the control processing circuit selects the first sensing circuit from a region corresponding to an outside of the first region.

17. The light-receiving element according to claim 4, wherein the control processing circuit selects a third region having a large change in luminance value on a basis of image data acquired from a second imaging unit and selects the second sensing circuit from a region corresponding to an inside of the third region.

18. The light-receiving element according to claim 17, wherein the control processing circuit selects the first sensing circuit from a region corresponding to an outside of the third region.

19. The light-receiving element according to claim 4, wherein
each of the plurality of pixels is independently drivable and includes a first pixel group and a second pixel group corresponding to the sensing circuit, and
in the first mode,
a pulse signal from a first sensing circuit group including the second sensing circuit is acquired from the first pixel group, and
a pulse signal from a second sensing circuit group that does not correspond to the first sensing circuit group is acquired from the second pixel group.

20. The light-receiving element according to claim 4, comprising a plurality of combinations of the first sensing circuit and the second sensing circuit, wherein
the control processing circuit selects from the combinations in accordance with a priority in the first mode.

21. The light-receiving element according to claim 4, wherein, in the first mode,
in a case where the counter circuit corresponding to the sensing circuit adjacent to the second sensing circuit exceeds a predetermined upper limit value, the control processing circuit selects the sensing circuit exceeding the predetermined upper limit value as the first sensing circuit.

22. An electronic apparatus comprising:
the light-receiving element according to claim 1; and
an optical system that supplies return light to the light-receiving element.
